(19) United States
(12) Patent Application Publication
(10) Pub. No.: US 2019/0177832 A1
(43) Pub. Date: Jun. 13, 2019

(54) INTEGRATED CHAMBER FOR VACUUM COATING

(71) Applicant: Beijing Chuangyu Technology Co., Ltd., Beijing (CN)

(72) Inventors: Manshi Yao, Beijing (CN); Feng Yan, Beijing (CN)

(21) Appl. No.: 16/122,177

(22) Filed: Sep. 5, 2018

(30) Foreign Application Priority Data
Dec. 13, 2017 (CN) 201711329989.0

(51) Int. Cl. C23C 14/24

(52) U.S. Cl. CPC C23C 14/24

(57) ABSTRACT

The present disclosure discloses an integrated chamber for vacuum coating, including an integrated chamber composed of a chamber top plate, four chamber side plates and a chamber bottom plate; wherein a baffle is provided in the integrated chamber, dividing the integrated chamber into a preheating chamber and a processing chamber; the baffle is provided with an opening for a workpiece to pass through, and a sealing door for blocking the opening is provided in the preheating chamber; the sealing door is hermetically fitted with the baffle, and the sealing door is connected with a first driving member so as to drive the sealing door to open and close. By integrating the preheating chamber and the processing chamber into an integrated chamber, the manufacturing process is improved and the assembly and maintenance are facilitated.

### CLAIM OF PRIORITY

This application claims priority to Chinese Patent Application No. 201711329989.0, filed Dec. 13, 2017, the entire contents of which are fully incorporated herein by reference.

### TECHNICAL FIELD

The present disclosure relates to the field of vacuum coating equipment, and particularly to an integrated chamber for vacuum coating.

### BACKGROUND

The preheating chamber and processing chamber of the existing coating equipment are generally independently manufactured, and are connected through an integrated gate valve to transfer workpieces and seal hermetically, so as to perform separately processes. For such structure, it is required that the two chambers are vacuum sealed respectively with a gate valve having a housing, then the partition and vacuum sealing between the two chambers are made by the valve spool of the gate valve. For such structure, when assembling the preheating chamber, gate valve and processing chamber, the gate valve (is usually very heavy) must be assembled with one of the chambers first and relevant vacuum test must be done. If qualified, the gate valve will be assembled with the other chamber and subjected to the vacuum test again. The workload and difficulty of assembly are great, and it is necessary to move the chambers to maintain the sealing rings between the gate valve and the chambers at a later stage, and the operation is performed with a crane or other lifting tools, which is very onerous. Under normal circumstances, fixed equipment should not be moved as much as possible so as to ensure the stability of the structural parameters of the equipment.

The existing heat insulation baffle behind the gate valve adopts a structure which moves straight up and down, which needs left and right support rods to mount the thermal insulation baffle in the chambers, and seals with welded bellows; further, it needs two guide rods, which may be driven pneumatically, electrically or manually. These thermal insulation baffles are usually mounted on the bottom of the processing chamber or behind the gate valve. The structures are all sized. The entire assembly will occupy about 100 mm in the length direction, then the bottom plate of the lower assembly of the processing chamber can be installed. The space including the bolts and the seal ring also needs to occupy about 80 to 90 mm in the length direction. It overall needs 180-190 mm space for assembly. The structure is relatively complex and requires relatively high manufacturing precision, and the upper and lower ends of the two bellows need to be vacuum sealed.

### SUMMARY

### (I) Technical Problem to be Solved

One of the objects of the present disclosure is to provide an integrated chamber for vacuum coating, so as to facilitate assembly and maintenance, and provide a heat insulation baffle with uncomplex structure and occupies no big large space.

### (II) Technical Solutions

The present disclosure provides an integrated chamber for vacuum coating, including an integrated chamber composed of a chamber top plate, four chamber side plates and a chamber bottom plate; wherein a baffle is provided in the integrated chamber, dividing the integrated chamber into a preheating chamber and a processing chamber; the baffle is provided with an opening for a workpiece to pass through, and a sealing door for blocking the opening is provided in the preheating chamber; the sealing door is hermetically fitted with the baffle, and the sealing door is connected with a first driving member which drives the sealing door to open and close.

In another respect, at least one swinging heat insulation plate is provided in the processing chamber, an end side of the swinging heat insulation plate is provided with a rotating shaft, one end of the rotating shaft is rotatably connected with a support which is mounted on the baffle or chamber wall of the integrated chamber, and the other end of the rotating shaft is connected with a second driving member; the second driving member drives the swinging heat insulation plate to open and close so as to match actions of the sealing door.

In another respect, the first driving member is a lifting cylinder; a driving shaft of the lifting cylinder is connected with the sealing door by passing through the chamber top plate , and the driving shaft of the lifting cylinder is hermetically connected with the chamber top plate.

In another respect, the second driving member is a swinging cylinder which is connected to the rotating shaft of the swinging heat insulation plate through a sealing bearing, so as to drive the swinging heat insulation plate to open and close; the sealing bearing is hermetically connected with the chamber wall of the integrated chamber.

In another respect, at least one fixing heat insulation plate is provided in the processing chamber, two ends of the fixing heat insulation plate are respectively fixed and connected to the chamber side plate, and a transmission opening though which the workpiece passes is provided on the fixing heat insulation plate.

In another respect, a peripheral side of the baffle is welded and fixed to an inner side of the integrated chamber.

In another respect, the chamber top plate is provided with upper openings respectively fitted with the preheating chamber and the processing chamber, the upper openings of the preheating chamber and the processing chamber are covered with a preheating chamber upper cover plate and the a processing chamber upper cover plate respectively; the chamber bottom plate is provided with a lower opening fitted with the processing chamber, and an outer side of the lower opening is covered with a processing chamber lower cover plate.

In another respect, the chamber top plate is an integral flange; sealing members are provided between the preheating chamber upper cover plate, the processing chamber upper cover plate and the chamber top plate; and sealing members are provided between the processing chamber lower cover plate and the chamber bottom plate.

In another respect, water cooling through holes are provided on the baffle and the chamber walls of the integrated chamber.

In another respect, sealing members are provided between the sealing door and the baffle.

In another respect, the integrated chamber is made of high-temperature resistant stainless steel.

### (III) Advantageous Effects

The integrated chamber for vacuum coating provided by the present disclosure improves the manufacturing process and facilitates the assembly and maintenance, by integrating the preheating chamber and the processing chamber into an integrated chamber; wherein the sealing door has a simple structure and small weight, is convenient for assembly and disassembly and maintenance, which reduces the cost; the swinging heat insulation plate has a simple structure, which occupies small space, reduces the size of the processing chamber and the amount of processing gas, and it is convenient to control the pressure, and the two ends thereof are connected and fixed by the rotating shaft, which facilitates the assembly, disassembly and maintenance, and also has reliable operation.

### BRIEF DESCRIPTION OF THE DRAWINGS

FIG. 1 is a longitudinal sectional view of an embodiment of the present disclosure;

FIG. 2 is a sectional view taken along A-A of FIG. 1.

In the figures: 1: sealing door; 2: swinging heat insulation plate; 3: fixing heat insulation plate; 4: workpiece; 5: processing chamber lower cover plate; 6: processing chamber upper cover plate; 7: preheating chamber upper cover plate 11; 8: first driving member; 9: sealing bearing; 10: second driving member; 11: baffle; 12: chamber top plate; 13: chamber side plate; 14: chamber bottom plate; 15: first rotating shaft; 16: support; O: swinging heat insulation plate opening state; S: swinging heat insulation plate closing state .

### DETAILED DESCRIPTION

The specific implementation manners of the present disclosure will be further described in detail with reference to the accompanying drawings and embodiments. The following examples are used to illustrate the present disclosure, but are not intended to limit the scope thereof.

In the description of the present disclosure, it should be noted that unless specifically defined or limited, the terms “mount”, “connect to”, and “connect with” should be understood in a broad sense, for example, they may be fixed connections or may be removable connections, or integrated connections; may be mechanical connections or electrical connections; they may also be direct connections or indirect connections through intermediate medium, or may be internal communication of two components. For a person of ordinary skill in the art, the specific meanings of the terms above in the present disclosure can be understood according to specific situations.

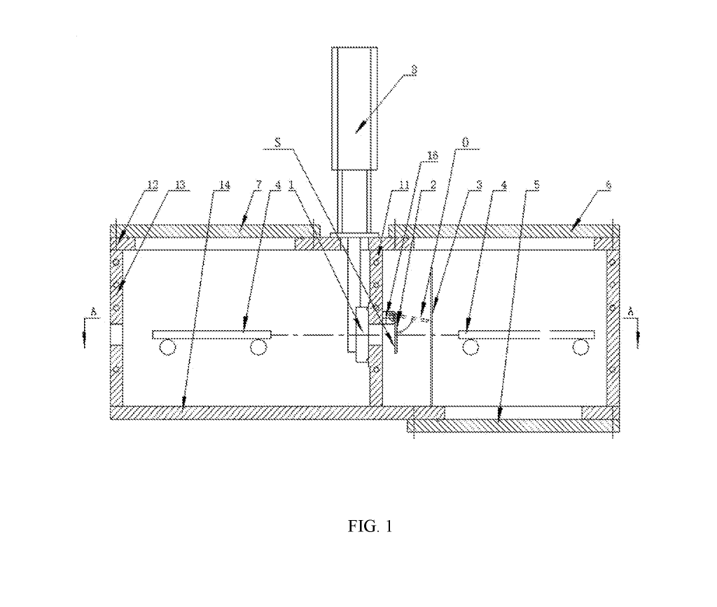

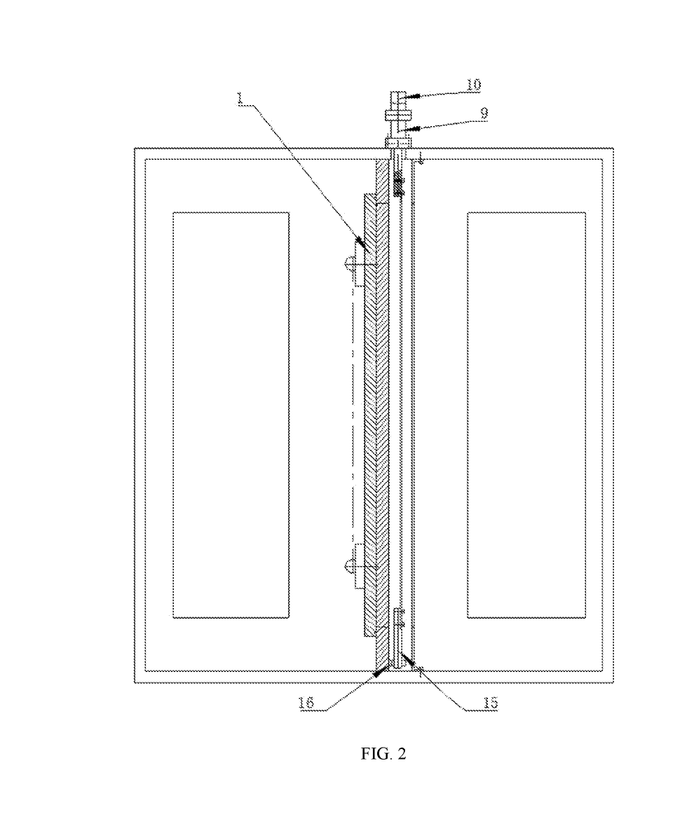

As shown in FIG. 1 and FIG. 2, an embodiment of the present disclosure provides an integrated chamber for vacuum coating, including an integrated chamber composed of a chamber top plate 12, four chamber side plates 13 and a chamber bottom plate 14; wherein a baffle 11 is provided in the integrated chamber, dividing the integrated chamber into a preheating chamber and a processing chamber; the baffle 11 is provided with an opening for a workpiece 4 to pass through, and a sealing door 1 for blocking the opening is provided in the preheating chamber; the sealing door 1 is hermetically fitted with baffle 11, and is connected with a first driving member 8 so as to drive the sealing door 1 to open and close.

Further, the integrated chamber is composed by welding the chamber top plate 12, the four chamber side plates 13 and the chamber bottom plate 14 together; the connection between each plate piece inside the integrated chamber adopts a continuous welding manner to achieve sealed connection, and the connection between each plate piece outside the integrated chamber adopts a spot welding manner to achieve fix connection, so as to ensure the overall structural strength.

The interior of the integrated chamber is partitioned into the preheating chamber and the processing chamber by the baffle 11; the peripheral side of the baffle 11 is welded and fixed to the inner wall of the integrated chamber. The baffle 11 at the processing chamber side is fixed to the inner wall of the integrated chamber by the continuous welding manner so as to ensure the sealing of the processing chamber; the baffle 11 at the preheating chamber side is fixed to the inner wall of the integrated chamber by the spot welding manner so as to enhance fixing strength of the baffle 11. Water cooling through holes for cooling the integrated chamber are provided on the baffle 11 and the chamber walls of the integrated chamber.

Further, the chamber top plate 12 is specifically an integral flange, and is provided with an upper opening fitted with the preheating chamber. The upper opening is covered with a preheating chamber upper cover plate 7. The chamber top plate 12 is also provided with an opening fitted with the processing chamber. The upper opening is covered with a processing chamber upper cover plate 6. The chamber bottom plate 14 of the processing chamber is provided with a lower opening, and the outer side of the lower opening is covered with a processing chamber lower cover plate 5, so as to facilitate disassembly and maintenance.

Sealing members are provided between the preheating chamber upper cover plate 7, the processing chamber upper cover plate 6 and the chamber top plate 12; and sealing members are also provided between the processing chamber lower cover plate 5 and the chamber bottom plate 14. The sealing member is preferably to be an O-shaped sealing ring so as to ensure the sealing of the preheating chamber and the processing chamber and improve the safety of the integrated chamber.

Further, the baffle 11 is provided with an opening. The size of the opening is greater than that of the workpiece 4 for the smooth passage of the workpiece 4. The sealing door 1 for blocking the opening is provided in the preheating chamber, and sealing members are provided between the sealing door 1 and the baffle 11. The sealing member is preferably to be an O-shaped sealing ring so as to achieve the sealing of the sealing door 1 with the baffle 11. The sealing members can prevent the air exchange between the preheating chamber and the processing chamber through the opening, which affects the coating effect.

The chamber top plate 12 is provided with a mounting hole fitted with the driving shaft of a first driving member 8. The first driving member 8 is preferably to be a lifting cylinder. The driving shaft of the lifting cylinder passes through the mounting hole and is connected to the sealing door 1, so as to drive the sealing door 1 to ascend or descend. The driving shaft of the lifting cylinder is hermetically mounted on the mounting hole of the chamber top plate 12 through a flange so as to ensure the sealing of the preheating chamber.

Further, at least one swinging heat insulation plate 2 is provided in the processing chamber. The number of the swinging heat insulation plates 2 is selected according to the actual temperature of the processing chamber, so as to protect the sealing door 1 and the O-shaped sealing ring between the sealing door 1 and the baffle 11 from the thermal radiation from the processing chamber, thereby extending the service life of the O-shaped sealing ring and ensuring the sealing of the preheating chamber and the processing chamber.

An end side of the swinging heat insulation plate 2 is provided with a rotating shaft. One end of the rotating shaft is rotatably connected with a support 16 which is mounted on the baffle 11 or the chamber wall of the integrated chamber; and the other end of the rotating shaft is connected with a second driving member 10. In another embodiment, one end of the swinging heat insulation plate 2 is fixedly connected to a first rotating shaft 15 by screws, the first rotating shaft 15 is rotatably mounted on the baffle 11 through the support 16; and the other end of the swinging heat insulation plate 2 is fixedly connected to the second rotating shaft by screws, the second rotating shaft is connected to an driving end of the second driving member 10. The embodiments both can realize that the second driving member 10 drives the swinging heat insulation plate 2 to open and close so as to match the action of the sealing door 1, which facilitates the assembly and disassembly and maintenance, and occupies small space.

Further, the second driving member 10 is preferably to be a swinging cylinder, the driving end thereof is provided with a sealing bearing 9 which is preferably to be a magnetic fluid bearing, so as to achieve that the swinging cylinder drives the swinging heat insulation plate 2 to open or close. The chamber side plate 13 is provided with a mounting hole fitted with the magnetic fluid bearing, so as to facilitate the assembly and disassembly and maintenance; and the sealed installation of the swing cylinder with the chamber side plate 13 can be achieved, and the swinging cylinder is sealed and assembled through the flange. The first rotating shaft 15 and the second rotating shaft are on the same horizontal line, so as to ensure that the swinging heat insulation plate 2 completely blocks the opening. It should be understood that in other embodiments of the present disclosure, the sealing between the driving end of the swinging cylinder and the chamber side plate 13 is not limited to the magnetic fluid bearing; and the movement of the swinging heat insulation plate 2 is not limited to swinging up and down along the moving direction of the workpiece 4. In some cases, it is also possible to swing left and right in the moving direction perpendicularly to the workpiece 4, or similar to the lifting movement of the sealing door 1.

Based on actual needs, at least one fixing heat insulation plate 3 parallel to the baffle 11 can be mounted in the processing chamber so as to assist the swinging heat insulation plate 2. Two ends of the fixing heat insulation plate 3 may be respectively fixed and connected to the chamber side plate 13 by screws or welding. A transmission opening fitted with the size of the workpiece 4 is provided on the fixing heat insulation plate 3, and the height of the fixing heat insulation plate 3 depends on the needs of the process and the relative positions of other components.

Further, when the workpiece 4 needs to be conveyed from the preheating chamber to the processing chamber, the lifting cylinder 8 drives the sealing door 1 to ascend to expose the opening on the baffle 11; at this time, it is in a swinging heat insulation plate closing state S, and the swinging cylinder 10 drives the swinging heat insulation plate 2 to rotate, and then it changes into a swinging heat insulation plate opening state O, so that the workpiece is smoothly conveyed to the processing chamber. The swinging cylinder 10 drives the swinging heat insulation plate 2 to restore to the closing state, the lifting cylinder 8 drives the sealing door 1 to descend, so that the sealing door 1 and the baffle 11 keeps sealed.

The sealing door 1, swinging heat insulation plate 2, fixing heat insulation plate 3, processing chamber lower cover plate 5, processing chamber upper cover plate 6, preheating chamber upper cover plate 7, baffle 11, chamber top plate 12, chamber side plate 13, first rotating shaft 15, second rotating shaft and support are made of high-temperature resistant stainless steel.

The integrated chamber for vacuum coating provided by the present disclosure improves the manufacturing process and facilitates the assembly and maintenance, by integrating the preheating chamber and the processing chamber into an integrated chamber; wherein the sealing door has a simple structure and small weight, is convenient for assembly and disassembly and maintenance, which reduces the cost; the swinging heat insulation plate has a simple structure which occupies small space, reduces the size of the processing chamber and the amount of processing gas, and it is convenient to control the pressure, and the two ends thereof are connected and fixed by the rotating shaft, which facilitates the assembly, disassembly and maintenance, and also has reliable operation.

The descriptions are merely preferred embodiments of the present disclosure and are not intended to limit the present disclosure. For example, the opening of the sealing door may be set to be opened by rotating along an offset shaft; the driving of the sealing door may be electrically or manually; the swinging heat insulation plate may be stacked with multiple layers separated by gaskets. Any modifications, equivalent replacements and improvements made within the spirit and principle of the present disclosure shall be within the protection scope of the present disclosure.

1. An integrated chamber for vacuum coating, comprising an integrated chamber composed of a chamber top plate, four chamber side plates and a chamber bottom plate;
wherein a baffle is provided in the integrated chamber, dividing the integrated chamber into a preheating chamber and a processing chamber;
the baffle is provided with an opening for a workpiece to pass through;
a sealing door for blocking the opening is provided in the preheating chamber; and
the sealing door is hermetically fitted with the baffle, and the sealing door is connected with a first driving member which drives the sealing door to open and close.

2. The integrated chamber for vacuum coating of claim 1, wherein at least one swinging heat insulation plate is provided in the processing chamber, an end side of the swinging heat insulation plate is provided with a rotating shaft, one end of the rotating shaft is rotatably connected with a support which is mounted on the baffle or chamber wall of the integrated chamber, and the other end of the rotating shaft is connected with a second driving member; the second driving member drives the swinging heat insulation plate to open and close so as to match actions of the sealing door.

3. The integrated chamber for vacuum coating of claim 2, wherein the first driving member is a lifting cylinder; a driving shaft of the lifting cylinder is connected with the sealing door by passing through the chamber top plate, and the driving shaft of the lifting cylinder is hermetically connected with the chamber top plate.

4. The integrated chamber for vacuum coating of claim 2, wherein the second driving member is a swinging cylinder which is connected to the rotating shaft of the swinging heat insulation plate through a sealing bearing, so as to drive the swinging heat insulation plate to open and close; the sealing bearing is hermetically connected with the chamber wall of the integrated chamber.

5. The integrated chamber for vacuum coating of claim 1, wherein at least one fixing heat insulation plate is provided in the processing chamber, two ends of the fixing heat insulation plate are respectively fixed and connected to the chamber side plate, and a transmission opening though which the workpiece passes is provided on the fixing heat insulation plate.

6. The integrated chamber for vacuum coating of claim 1, wherein a peripheral side of the baffle is welded and fixed to an inner wall of the integrated chamber.

7. The integrated chamber for vacuum coating of claim 1, wherein the chamber top plate is provided with upper openings respectively fitted with the preheating chamber and the processing chamber, the upper openings of the preheating chamber and the processing chamber are covered with a preheating chamber upper cover plate and the a processing chamber upper cover plate respectively; the chamber bottom plate is provided with a lower opening fitted with the processing chamber, and an outer side of the lower opening is covered with a processing chamber lower cover plate.

8. The integrated chamber for vacuum coating of claim 7, wherein the chamber top plate is an integral flange;
sealing members are provided between the preheating chamber upper cover plate, the processing chamber upper cover plate and the chamber top plate; and
sealing members are provided between the processing chamber lower cover plate and the chamber bottom plate.

9. The integrated chamber for vacuum coating of claim 1, wherein water cooling through holes are provided on the baffle and the chamber walls of the integrated chamber.

10. The integrated chamber for vacuum coating of claim 1, wherein sealing members are provided between the sealing door and the baffle.

11. The integrated chamber for vacuum coating of claim 1, wherein the integrated chamber is made of high-temperature resistant stainless steel.
